(19) United States
(12) Patent Application Publication
(10) Pub. No.: US 2010/0244190 A1
(43) Pub. Date: Sep. 30, 2010

(54) SEMICONDUCTOR DEVICE AND MANUFACTURING METHOD

(76) Inventor: TOSHIHIKO NAKANO, Tokyo (JP)

Correspondence Address: Mr. Jackson Chen, 6535 N. STATE HWY 161, IRVING, TX, 75039, US

(21) Appl. No.: 12/698,600

(22) Filed: Feb. 2, 2010

(30) Foreign Application Priority Data
Mar. 24, 2009 (JP) 71866/2009

(51) Int. Cl. H01L 29/92; H01L 21/02

(52) U.S. Cl. 257/532; 438/396; 257/E21.008; 257/E29.343

(57) ABSTRACT

A semiconductor device, include a capacitor of a MIM (Metal-Insulator-Metal) structure; and at least one pair of shield parts which sandwich said MIM structure capacitor sandwiched by an insulating film.

This application is based upon and claims the benefit of priority from Japanese Patent Application No. 2009-071866, filed on Mar. 24, 2009, the disclosure of which is incorporated herein in its entirety by reference.

1. Technical Field

The present invention relates to a semiconductor device and the manufacturing method thereof.

2. Background Art

In order to respond to the request to the semiconductor device such as a speedup of the operation speed, a multi-core technology is used today. This multi-core technology is a technology which improves processing performance of a semiconductor device as a whole by mounting a plurality of processor cores in one semiconductor device and making each processor core operate.

However, because such a multi-core technology causes an increase of power consumption, fluctuation of an electric potential of a power supply line and a ground line (so-called power supply noise) becomes a problem. In particular, in a semiconductor device for which a multi-core technology is used, a problem related to power supply noise becomes remarkable, because enormous numbers of transistors are mounted on it.

Accordingly, a technology to suppress the power consumption by enabling to change the operating frequency and the power supply voltage of a processor core is being proposed. However, even if the power consumption is suppressed by the technology, signal integrity and power integrity are the large problems.

A technology for maintaining signal integrity and power integrity is also proposed. In Japanese Patent Application Laid-Open No. 1985-154644 and Japanese Patent Application Laid-Open No. 2006-344639, a structure in which a power supply line is arranged between signal lines as a measure against crosstalk noise is disclosed. Crosstalk noise between the signal lines can be reduced by shielding each of the signal lines by this power supply line.

On the other hand, as a measure against power supply noise, in Japanese Patent Application Laid-Open No. 2004-327619, there is proposed a structure in which an interlaminar line is arranged between a power supply line and a ground line and an under the interlaminar line a capacitor of the MIM (Metal-Insulator-Metal) structure is formed. This MIM structure capacitor can suppress power supply noise, because it functions as a bypass capacitor. Also, because the MIM structure capacitor is shielded by the interlaminar line, parasitic capacitance which occurs between a signal line and the MIM structure capacitor can be suppressed. Meanwhile, parasitic capacitance is a cause of such as the signal delay. Hereinafter, a MIM structure capacitor is described as a MIM capacitor.

Although the technologies according to Japanese Patent Application Laid-Open No. 1985-154644 and Japanese Patent Application Laid-Open No. 2006-344639 are effective against crosstalk noise, there is a problem that power supply noise cannot be suppressed.

In Japanese Patent Application Laid-Open No. 2004-327619, there is a problem that parasitic capacitance between a signal line and a MIM capacitor cannot be suppressed when the signal line is arranged under a MIM capacitor, because an interlaminar line is provided only in a position over the MIM capacitor. In particular, in a semiconductor device using a multi-core technology, it is requested to a MIM capacitor for suppressing power supply noise that it has a large capacity and that it is arranged in a plurality of positions. Accordingly, parasitic capacitance between a MIM capacitor and a signal line which is wired in a position under the MIM capacitor where an interlaminar line is not provided also becomes large.

Therefore, in a wiring layout design of a semiconductor device, it is thinkable that the design is performed in consideration of parasitic capacitance. However, in this case, a time consuming effort to make a wiring tool and an extraction tool extract a MIM capacitor is required. In addition, determination whether signal delay caused by extracted parasitic capacitance is within an allowable range or not is needed to be made. When the allowable range is small, parasitic capacitance has to be evaluated with a high degree of accuracy. For this reason, the working hours are increased, because a wiring position and a numerical value of such as a resistance and a capacitor have to be calculated with a high degree of accuracy.

### SUMMARY

An exemplary object of the present invention is to provide a semiconductor device and a manufacturing method which enable to suppress parasitic capacitance occurring between a signal line and a MIM capacitor regardless of the position of the signal line.

A semiconductor device, include a capacitor of a MIM (Metal-Insulator-Metal) structure; and at least one pair of shield parts which sandwich said MIM structure capacitor sandwiched by an insulating film.

A manufacturing method of a semiconductor device, include a step for forming an under shield part; a step for forming a first insulating film and a MIM structure capacitor in this order on said under shield part; and a step for forming a second insulating film and an upper shield part in this order on said MIM structure capacitor.

### BRIEF DESCRIPTION OF THE DRAWINGS

Exemplary features and advantages of the present invention will become apparent from the following detailed description when taken with the accompanying drawings in which:

FIG. 1 is a fragmentary sectional view of a semiconductor device of a first exemplary embodiment according to the present invention;

FIG. 2 is a partial top view of a semiconductor device of a second exemplary embodiment according to the present invention;

FIG. 3 is a magnified view of area A in FIG. 2;

FIG. 4 is a sectional view of a semiconductor device taken along line B-B of FIG. 3;

FIG. 5 is a sectional view of a semiconductor device taken along line C-C of FIG. 3;

FIG. 6 is a sectional view of a semiconductor device taken along line D-D of FIG. 3;

FIG. 7 is a fragmentary sectional view of a semiconductor device of another structure as an alternative of that of FIG. 4;

FIG. 8 is a flowchart showing a manufacturing method of a semiconductor device;

FIG. 9 is a partial top view of a semiconductor device of a third exemplary embodiment according to the present invention;

FIG. 10 is a sectional view of a semiconductor device taken along line E-E of FIG. 9;

FIG. 11 is a sectional view of a semiconductor device taken along line F-F of FIG. 9; and

FIG. 12 is a sectional view of a semiconductor device taken along line G-G of FIG. 9.

### EXEMPLARY EMBODIMENT

A First Exemplary Embodiment

A first exemplary embodiment of the present invention will be described with reference to drawings.

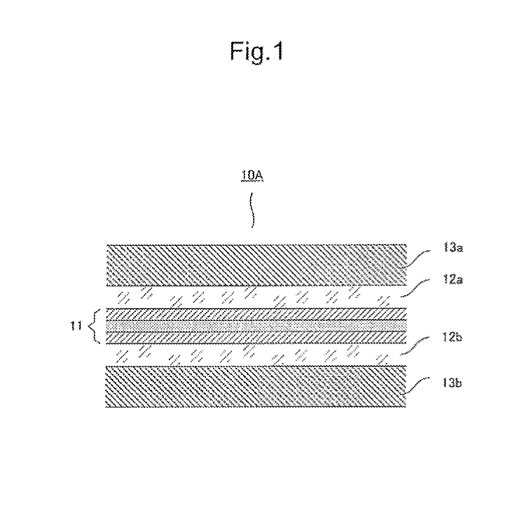

FIG. 1 is a fragmentary sectional view of a semiconductor device 10A according to the first exemplary embodiment. This semiconductor device 10A has a pair of shield parts 13a and 13b. The pair of shield parts 13a and 13b shields a capacitor 11 of a MIM (Metal-Insulator-Metal) structure electrically by sandwiching the MIM capacitor 11 sandwiched by insulating films 12a and 12b. Hereinafter, a capacitor of a MIM structure is described as a MIM capacitor.

By this structure, even if a signal line (not shown) is arranged near the MIM capacitor 11, for example, the MIM capacitor 11 is shielded by the shield parts 13a and 13b. Accordingly, parasitic capacitance which occurs between the MIM capacitor 11 and the signal line can be suppressed.

Therefore, layout design of a signal line can be performed without considering parasitic capacitance between the signal line and the MIM capacitor 11.

A Second Exemplary Embodiment

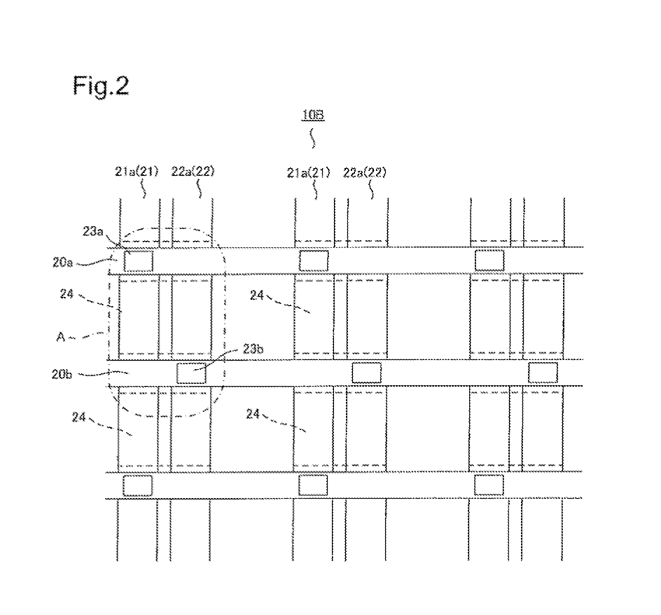

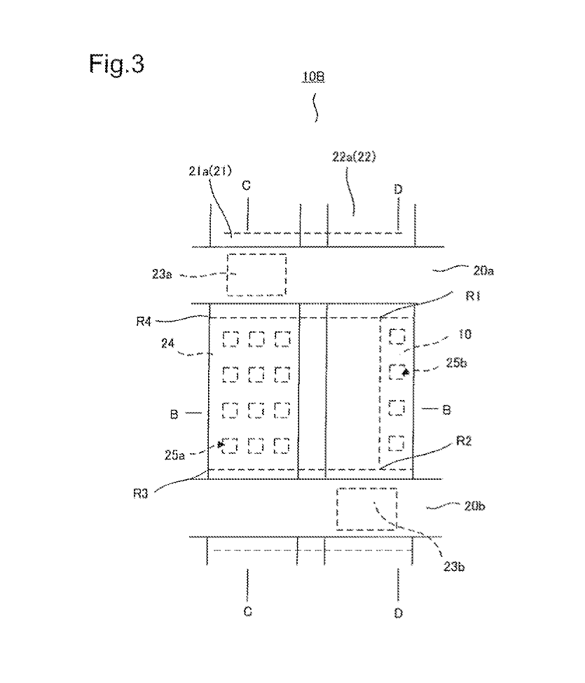

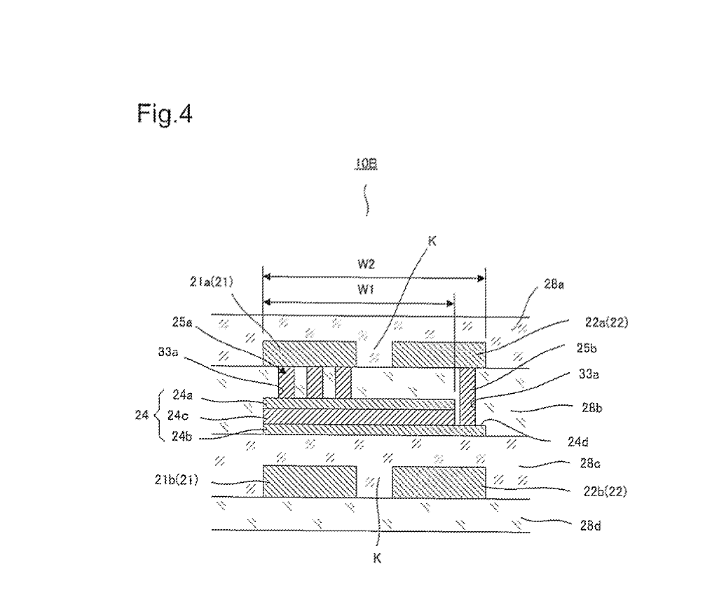

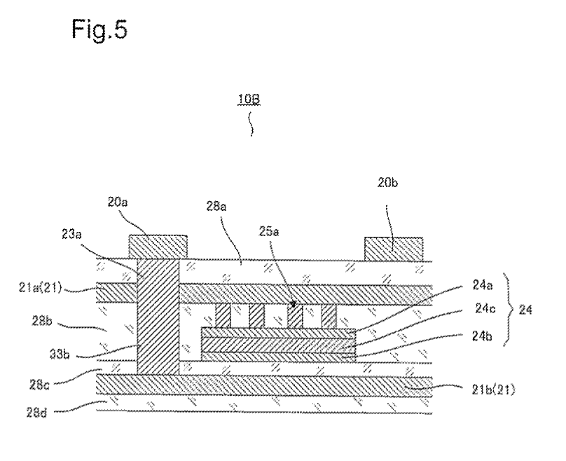

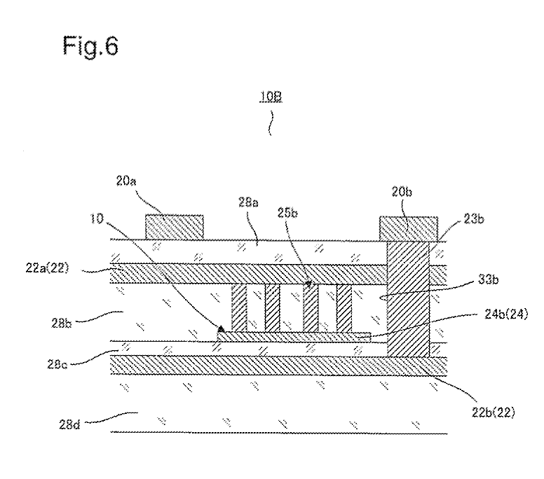

Next, a second exemplary embodiment of the present invention will be described with reference to drawings. FIG. 2 is a partial top view of a semiconductor device 10B provided with a MIM capacitor 24 according to the second exemplary embodiment. FIG. 3 is a magnified view of area A in FIG. 2. FIG. 4 is a sectional view taken along line B-B of FIG. 3, FIG. 5 is a sectional view taken along line C-C of FIG. 3 and FIG. 6 is a sectional view taken along line D-D of FIG. 3.

This semiconductor device 10B includes a VDD line 21, a GND line 22, a bridge VDD line 20a, a bridge GND line 20b, the MIM capacitor 24, VDD connecting line 23a, a GND connecting line 23b, a VDD electrode line 25a and a GND electrode line 25b. Meanwhile, the bridge VDD line 20a, the bridge GND line 20b, the VDD line 21 and the GND line 22 are wiring to provide electric power supply to standard cells in a power-supply-line mesh structure, but not dedicated VDD lines for the MIM capacitor 24. In this specification, the power supply potential is indicated as VDD, and the ground potential is indicated as GND. For example, the VDD line 21 is wiring of the power supply potential and a GND line shows that it is wiring of the ground potential. These are described as a power supply line as the collective term.

The VDD line 21 and the GND line 22 are divided into two layers (upper and under), and are arranged in parallel with each other as shown in FIGS. 4-6. Hereinafter, the VDD line 21 that is arranged in the upper side is described as an upper VDD line 21a and the VDD line 21 arranged in the lower side is described as an under VDD line 21b. Similarly, the GND line 22 that is arranged in the upper side is described as an upper GND line 22a and the GND line 22 arranged in the lower side is described as an under GND line 22b. The upper VDD line 21a and the upper GND line 22a are formed in an identical layer, and the under VDD line 21b and the under GND line 22b are formed in an identical layer. The bridge VDD line 20a and the bridge GND line 20b are formed in an identical layer. The bridge VDD line 20a and the bridge GND line 20b are formed in a position orthogonal to the VDD line 21 and the GND line 22.

As shown in FIG. 4, an insulating film 28a is provided in a layer above the upper VDD line 21a and the upper GND line 22a, and an insulating film 28d is arranged in a layer bellow the under VDD line 21b and the under GND line 22b. Insulating films 28b and 28c are provided in this order from above between the upper VDD line 21a and the upper GND line 22a, and the under VDD line 21b and the under GND line 22b. The MIM capacitor 24 is arranged between the insulating film 28b and the insulating film 28c. The upper VDD line 21a, the under VDD line 21b, the upper GND line 22a and the under GND line 22b function as a shield part which shields the MIM capacitor 24 electrically.

As shown in FIG. 3, the MIM capacitor 24 forms a rectangular shape when seen from the top surface along the lengthwise direction of the VDD line 21 and the GND line 22 (the area surrounded with points R1, R2, R3 and R4 of FIG. 3). As shown in such as FIG. 4, this MIM capacitor 24 includes an electrode 24a, an electrode 24b and a dielectric material 24c provided between the electrodes 24a and 24b.

The electrode 24a and 24b of the MIM capacitor 24 are arranged in parallel with the surfaces of the upper VDD line 21a, the under VDD line 21b, the upper GND line 22a and the under GND line 22b. Accordingly, the electrode 24a is described as the upper part electrode 24a and the electrode 24b are described as the under part electrode 24b. However, distinction of the upper part and the under part is not intended to exclude a case where the MIM capacitor 24 is formed such that its electrode surface is arranged vertically to the face of such as the upper VDD line 21 a like a trench structure, for example. That is, a MIM capacitor in this exemplary embodiment may be a capacitor of trench structure.

As shown in FIG. 4, a side of the under part electrode 24b is formed such that it projects from a side of the upper part electrode 24a and a side of the dielectric material 24c, and this projecting part forms a connection terminal 24d of the under part electrode 24b. Further, the surface of the upper part electrode 24a in the upper VDD line 21a side forms a connection terminal of the upper part electrode 24a.

In FIG. 4, dimension W1 of the MIM capacitor 24 in the width direction of the VDD line 21 and the GND line 22 is set to a smaller size than the width dimension W2 formed by these VDD line 21 and GND line 22. When the MIM capacitor 24 sticks out of the VDD line 21 and the GND line 22, shielding of this sticking out portion becomes insufficient. For this reason, the size W1 is made smaller than the size W2.

Meanwhile, the area of the MIM capacitor 24 corresponding to gap area K (refer to FIG. 4) between the VDD line 21 and the GND line 22 is not covered by these VDD line 21 and GND line 22. However, because a signal line which is coupled capacitively via the region between the VDD line 21 and the GND line 22 is to be provided in an under layer below the insulating film 28d or in an upper layer above the bridge VDD line 20a and the bridge GND line 20b, the distance between the signal line and the MIM capacitor 24 becomes large. Because parasitic capacitance is in inverse proportion to the distance, parasitic capacitance formed between the signal line and the MIM capacitor 24 also becomes small. Accordingly, even if a certain degree of gap area K exists between the VDD line 21 and the GND line 22, it will not be a substantial problem.

As shown in FIG. 5, the VDD connecting line 23a connects the bridge VDD line 20a, the upper VDD line 21a and the under VDD line 21b, and as shown in FIG. 6, the GND connecting line 23b connects the bridge GND line 20b, the upper GND line 22a and the under GND line 22b. The VDD connecting line 23a is provided through the upper VDD line 21a, and the GND connecting line 23b is provided through the upper GND line 22a.

On the other hand, as shown in FIG. 4 and FIG. 5, the VDD electrode line 25a connects the upper VDD line 21a and the upper part electrode 24a of the MIM capacitor 24, and as shown in FIG. 4 and FIG. 6, the GND electrode line 25b connects the upper GND line 22a and the connection terminal 24d in the under part electrode 24b.

By such VDD connecting line 23a, the upper VDD line 21a and the under VDD line 21b sandwiching the MIM capacitor 24 are set to a same electric potential. Similarly, by the GND connecting line 23b, the upper GND line 22a and the under GND line 22b sandwiching the MIM capacitor 24 become a same electric potential. Accordingly, the MIM capacitor 24 is shielded.

Meanwhile, the signal line is also capacitively coupled with the upper and under VDD lines 21a and 21b, and with the upper and under GND lines 22a and 22b. However, because the upper VDD line 21a and the under VDD line 21b are at a same electric potential and the upper GND line 22a and the under GND line 22b are at a same electric potential again, the upper and under VDD lines 21a, 21b, and the upper and under GND lines 22a, 22b cause mirror image effect to a signal of the signal line. Accordingly, signal delay or the like by parasitic capacitance becomes very small.

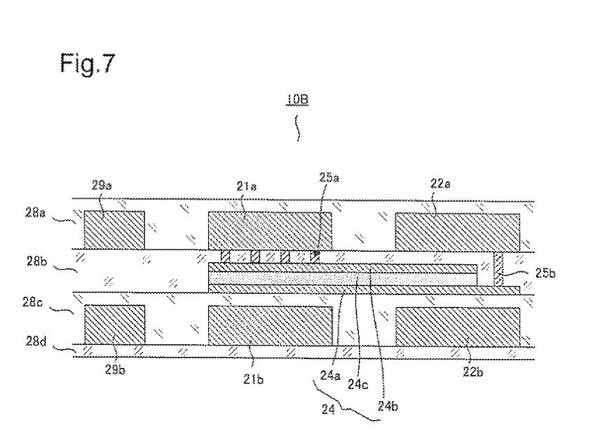

As shown in FIG. 7, there is a case where signal lines 29a and 29b is formed in the same layers as the upper and under VDD lines 21a, 21b, and the upper and under GND lines 22a, 22b. Such signal lines 29a and 29b are capacitively coupled with the MIM capacitor 24. Because the positional relation between the signal line 29a and the MIM capacitor 24 and between the signal line 29b and the MIM capacitor 24 is of oblique relation, the distance between them becomes large. Because a value of parasitic capacitance is in inverse proportion to the distance, parasitic capacitance between them becomes small. For example, parasitic capacitance when the signal lines 29a and 29b and the MIM capacitor 24 are in oblique relation can be no more than one-several tenth of parasitic capacitance when the signal lines 29a and 29b is formed over or under the MIM capacitor 24. In addition, when the left-to-right width W1 (refer to FIG. 4) of the MIM capacitor 24 is made smaller than the width W2 (also, refer to FIG. 4) formed by the upper and under VDD lines 21a, 21b and by the upper and under GND lines 22a, 22b, the distance between the signal lines 29a and 29b and the MIM capacitor 24 becomes long by just that much, and thus it is possible to reduce the parasitic capacitance further.

As it has been described above, because the MIM capacitor 24 is shielded by sandwiching the MIM capacitor 24 by the upper and under VDD lines 21a, 21b and by the upper and under GND lines 22a, 22b, the engineer does not almost have the necessity of considering the parasitic capacitance between the signal line and the MIM capacity in the layout design. Therefore, design man-hours can be reduced.

In addition, power supply noise can be suppressed effectively, because the MIM capacitor 24 can be arranged in needed portions along a power supply line (the upper and under VDD lines 21a, 21b and the upper and under GND lines 22a, 22b) in a power-supply-line mesh structure.

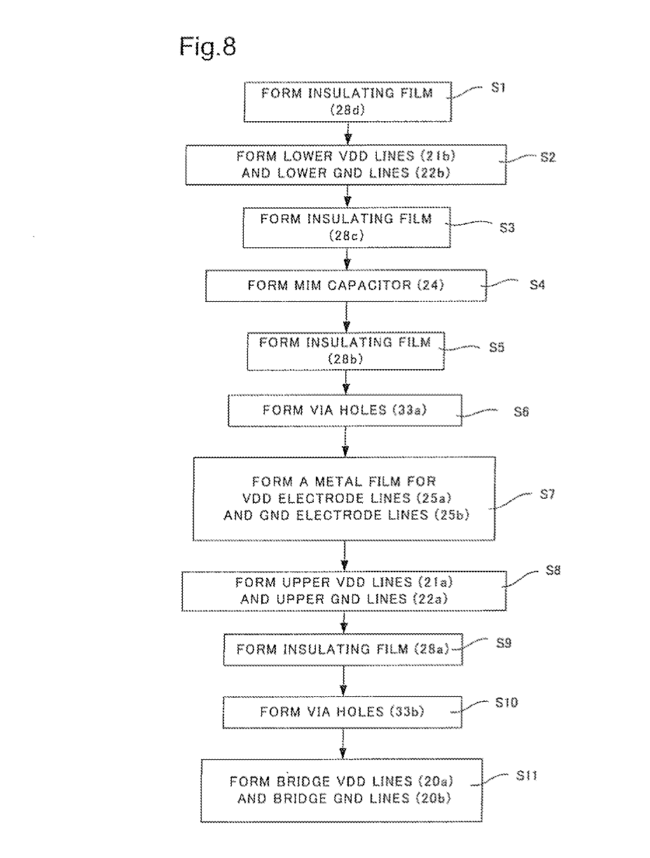

Next, the manufacturing method of a semiconductor device according to this second exemplary embodiment will be described with reference to FIG. 8. Meanwhile, description of steps for forming a transistor or the like on a semiconductor substrate which is not illustrated will be omitted. In the following description, it begins from the step for forming the insulating film 28d as a foundation onto which the MIM capacitor 24 and the like is formed (Step S1).

Meanwhile, the insulating films 28a-28d and the dielectric material 24c of the MIM capacitor 24 can be produced using a general film generation method such as a plasma CVD (Plasma-enhanced chemical vapor deposition) method. As its material, an electric insulation substance such as silicon oxide (SiO), silicon nitride (SiN) or complexes of these materials can be used.

Next, the under VDD line 21b and the under GND line 22b are formed onto the insulating film 28d (Step S2). Further, a general film generation method such as a sputtering method can be applied for the VDD lines 21a, 21b, the GND lines 22a, 22b, the bridge VDD line 20a, the bridge GND line 20b, the VDD connecting line 23a, the GND connecting line 23b, the VDD electrode line 25a, the GND electrode line 25b, the upper part electrode 24a and the under part electrode 24b in the MIM capacitor 24 or the like. As its material, metal such as titanium (Ti), tungsten (W), tungsten silicide (WSix), tungsten silicide nitride (WSiN), tantalum (Ta), platinum (Pt), gold (Au), nickel (Ni), aluminum (Al) and copper (Cu) can be used.

These metallic films are patterned in a predetermined pattern using a photolithography technique and etching technology. Further, an electron beam exposure method may be used. In such a step, a resist is applied on an insulating film or metallic film, and the latent image of a resist pattern is formed using a mask. Then, by development using a developing fluid, a predetermined resist pattern is obtained. After that, an insulating film or a metallic film is patterned by wet etching using etchant or dry etching using a reactive gas (etching gas) or an ion radical utilizing the resist pattern as an etching mask. Hereinafter, such technology is called an exposure and etching technology.

Next, the insulating film 28c is formed (Step S3), and the MIM capacitor 24 is formed on this insulating film 28c (Step S4). Meanwhile, description of the forming method of the insulating film 28c is omitted, because it is similar to the insulating film 28d mentioned above.

The MIM capacitor 24 is formed such that a metallic film which becomes the material of the under part electrode 24b is formed first and a dielectric film which becomes the material of the dielectric material 24c and a metallic film which becomes the material of the upper part electrode 24a are formed successively on it. By etching these films using an exposure and etching technology, the MIM capacitor 24 is formed.

Next, the insulating film 28b is formed (Step S5), and a via hole (contact hole) 33a (refer to FIG. 4) is formed into this insulating film 28b using an exposure and etching technology (Step S6). After that, a metallic film which becomes the material of the VDD electrode line 25a and the GND electrode line 25b is formed in the via hole 33a (Step S7).

The via hole 33a is formed by etching the insulating film 28b using the upper part electrode 24a and the connection terminal 24d as an etching stopper. A metallic film which becomes the material of the VDD electrode line 25a and the GND electrode line 25b is embedded in this via hole 33a. A metallic film embedded in this via hole 33a connects with the upper part electrode 24a and the connection terminal 24d electrically.

Next, a metallic film which becomes the material of the upper VDD line 21a and the upper GND line 22a is formed, and the upper VDD line 21a and the upper GND line 22a are formed using an exposure and etching technology (Step S8).

After that, the insulating film 28a is formed (Step S9), and a via hole 33b (refer to FIG. 5 and FIG. 6) is formed using an exposure and etching technology (Step S10). After forming the via hole 33b, a metallic film which becomes the material of the bridge VDD line 20a and the bridge GND line 20b is formed, and the bridge VDD line 20a and the bridge GND line 20b are formed using an exposure and etching technology (Step S11).

Meanwhile, in the steps mentioned above, although Step S2 is a step needed in particular when a semiconductor device according to the second exemplary embodiment is produced, the other steps are steps used for a general semiconductor device. This means that a semiconductor device in which occurrence of parasitic capacitance is suppressed can be produced only by adding a small number of steps. Therefore, a semiconductor device in which occurrence of parasitic capacitance is suppressed can be produced cheaply.

A Third Exemplary Embodiment

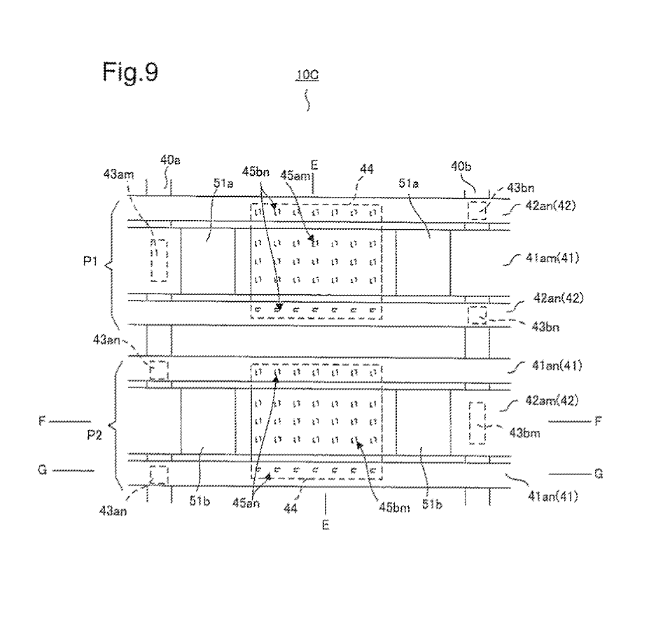

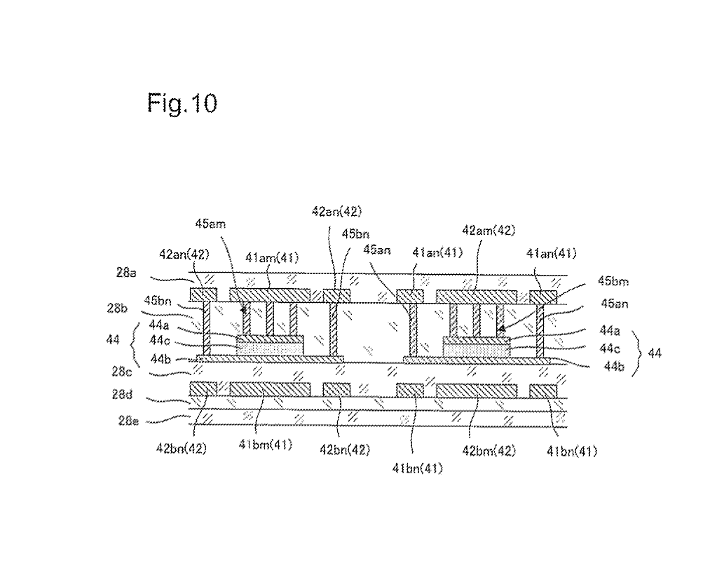

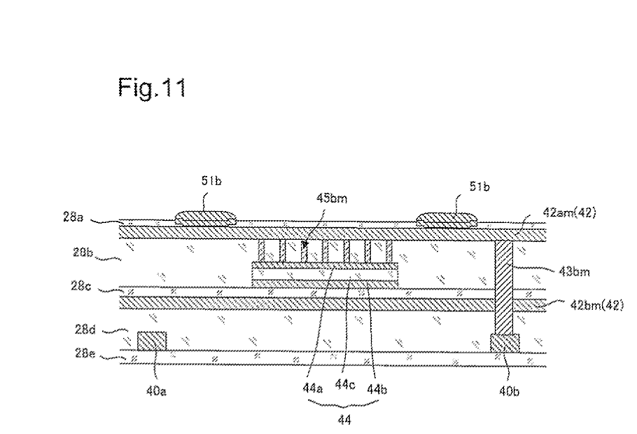

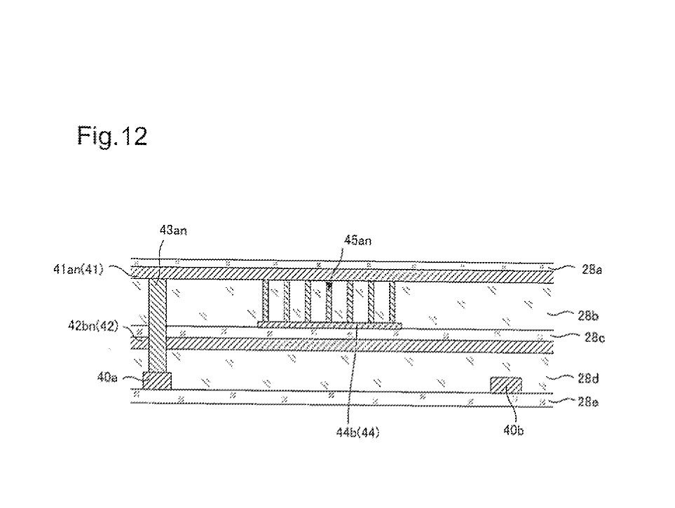

Next, a third exemplary embodiment of the present invention will be described. FIG. 9 is a partial top view of a semiconductor device according to this exemplary embodiment, FIG. 10 is a sectional view of a semiconductor device taken along line E-E of FIG. 9, FIG. 11 is a sectional view of a semiconductor device taken along line F-F of FIG. 9 and FIG. 12 is a sectional view of a semiconductor device taken along line G-G of FIG. 9.

The third exemplary embodiment as a semiconductor device 10C of a flip chip structure is provided with VDD line pads 51a and 51b used as solder bumps. In this kind of semiconductor device 10C, a VDD line 41 and a GND line 42 in which a solder bump is formed are formed as a wiring layer of the highest layer.

That is, this semiconductor device 10C is provided with the VDD line 41, the GND line 42, a bridge VDD line 40a, a bridge GND line 40b, a MIM capacitor 44, VDD connecting lines 43am and 43an, GND connecting lines 43bm and 43bn, VDD electrode lines 45am and 45an, GND electrode lines 45bm and 45bn, an insulating films 28a, 28b, 28c, 28d and 28e. Further, the number 51a is a VDD pad for a solder bump, and the number 51b is a GND pad.

The VDD line 41 and the GND line 42 are not exclusive use VDD lines of the MIM capacitor 44, but are wiring which supply power to standard cells in a power-supply-line mesh structure.

The VDD line 41 includes an upper VDD line 41am which is arranged over the MIM capacitor 44 and the line width of which is large, and an upper VDD line 41an the line width of which is smaller than that of the upper VDD line 41am, and also includes an under VDD line 41bm which is arranged under the MIM capacitor 44 and the line width of which is large and an under VDD line 41bn the line width of which is smaller than that of the under VDD line 41bm.

The GND line 42 includes an upper GND line 42am which is arranged over the MIM capacitor 44 and line width of which is large, and an upper GND line 42an the line width of which is smaller than that of the upper GND line 42am, and also includes an under GND line 42bm which is arranged over the MIM capacitor 44 and line width of which is large and an under GND line 42bn the line width of which is smaller than that of the under GND line 42bm.

Here, as shown in FIG. 9 and FIG. 10, the broad upper VDD line 41am and the broad under VDD line 41bm are sandwiched by two narrow upper GND line 42an and two narrow under GND line 42bn, respectively (refer to area P1 of FIG. 9).

Similarly, the broad upper GND line 42am and the broad under GND line 42bm are sandwiched by two narrow upper VDD line 41an and two narrow under VDD line 41bn, respectively (refer to area P2 of FIG. 9).

In FIG. 9, area P1 and area P2 are formed in the longitudinal direction of the bridge VDD line 40a and the bridge GND line 40b being arranged one after the other in the vertical direction of the sheet.

A VDD connecting line 43am connects the broad upper VDD line 41am, the broad under VDD line 41bm and the bridge VDD line 40a (refer to area P1 of FIG. 9). A VDD connecting line 43an connects the narrow upper VDD line 41an, the narrow under VDD line 41bn and the bridge VDD line 40a (refer to area P2 of FIG. 9, and FIG. 12).

Similarly, a GND connecting line 43bm connects the broad upper GND line 42am, the broad under GND line 42bm and the bridge GND line 40b (refer to area P2 of FIG. 9, and FIG. 11). Also, a GND connecting line 43bn connects the narrow upper GND line 42an, the narrow under GND line 42bn and the bridge GND line 40b (refer to area P1 of FIG. 9).

A VDD electrode line 45am connects the broad upper VDD line 41am and an upper part electrode 44a of the MIM capacitor 44 (refer to area P1 of FIG. 9, and FIG. 10). A VDD electrode line 45an connects the narrow upper VDD line 41an and a under part electrode 44b of the MIM capacitor 44 (refer to area P2 of FIG. 9, and FIG. 10).

Similarly, a GND electrode line 45bn connects the narrow upper GND line 42an and the under part electrode 44b of the MIM capacitor 44 (refer to area P1 of FIG. 9). A GND electrode line 45bm connects the broad upper GND line 42am and the upper part electrode 44a of the MIM capacitor 44 (refer to area P2 of FIG. 9).

As shown in area P1 of FIG. 9, the broad upper GND line 41am is sandwiched by the narrow upper VDD lines 42an and the broad under GND line 41bm is sandwiched by the narrow under VDD lines 42bn. Further, as shown in area P2, the broad upper VDD line 42am is sandwiched by the narrow upper GND lines 41an and the broad under VDD line 41bm is sandwiched by the narrow under GND lines 42bn.

Thus, the reason why a broad VDD line is sandwiched by narrow GND lines, and also a broad GND line is sandwiched by narrow VDD lines is in order to reduce connection resistance with the MIM capacitor 44. Accordingly, for the purpose of shielding the MIM capacitor 44 by the VDD line 41 and the GND line 42, it is not necessarily required to sandwich a broad VDD line by narrow GND lines, and also to sandwich a broad GND line by narrow VDD lines.

Because a VDD line and a GND line in which a solder bump is formed are formed as the uppermost wiring layer, there is no need to provide wiring which becomes a shielding layer on them. On the other hand, because the under VDD line 41bm, 41bn, the under GND line 42bm and 42bn are formed under the MIM capacitor 44, the MIM capacitor 44 is shielded to a signal line which is not illustrated. Therefore, parasitic capacitance which occurs between a signal line and a MIM capacitor can be suppressed regardless of an arrangement position of the signal line.

The previous description of embodiments is provided to enable a person skilled in the art to make and use the present invention. Moreover, various modifications to these exemplary embodiments will be readily apparent to those skilled in the art, and the generic principles and specific examples defined herein may be applied to other embodiments without the use of inventive faculty. Therefore, the present invention is not intended to be limited to the exemplary embodiments described herein but is to be accorded the widest scope as defined by the limitations of the claims and equivalents.

Further, it is noted that the inventor's intent is to retain all equivalents of the claimed invention even if the claims are amended during prosecution.

1. A semiconductor device, comprising:
a capacitor of a MIM (Metal-Insulator-Metal) structure; and
at least one pair of shield parts which sandwich said MIM structure capacitor sandwiched by an insulating film.

2. The semiconductor device according to claim 1, wherein
a pair of said shield parts sandwiching said MIM structure capacitor are at a fixed electric potential respectively.

3. The semiconductor device according to claim 2, wherein
said shield parts are connected with a power supply line in said semiconductor device.

4. The semiconductor device according to claim 2, wherein.
a pair of said shield parts comprises a first shield part which is connected to one electrode of said MIM structure capacitor;
a second shield part connected to another electrode of said MIM structure capacitor.

5. The semiconductor device according to claim 3, wherein.
said power supply line is wired to a power-supply-line mesh structure.

6. The semiconductor device according to claim 1, wherein.
said shield parts are wiring of a power supply potential or a ground potential.

7. The semiconductor device according to claim 1, wherein
said shield parts cover said MIM structure capacitor.

8. The semiconductor device according to claim 1, wherein
said MIM structure capacitor is a MIM structure capacitor which absorbs power supply noise.

9. A manufacturing method of a semiconductor device, comprising:
a step for forming an under shield part;
a step for forming a first insulating film and a MIM structure capacitor in this order on said under shield part; and
a step for forming a second insulating film and an upper shield part in this order on said MIM structure capacitor.

10. The manufacturing method of a semiconductor device according to claim 9, wherein
said method further comprises a step for connecting said upper shield part and said under shield part electrically.
